(19) United States
(12) Patent Application Publication
(10) Pub. No.: US 2016/0189963 A1
(43) Pub. Date: Jun. 30, 2016

(54) DOPING METHOD AND SEMICONDUCTOR ELEMENT MANUFACTURING METHOD

(71) Applicant: TOKYO ELECTRON LIMITED, Tokyo (JP)

(72) Inventors: Hirokazu UEDA, Yamanashi (JP); Masahiro OKA, Yamanashi (JP); Yuuki KOBAYASHI, Miyagi (JP); Yasuhiro SUGIMOTO, Yamanashi (JP)

(73) Assignee: TOKYO ELECTRON LIMITED, Tokyo (JP)

(21) Appl. No.: 14/976,456

(22) Filed: Dec. 21, 2015

(30) Foreign Application Priority Data
Dec. 25, 2014 (JP) 2014-262813

(51) Int. Cl. H01L 21/223; H01L 21/225

(52) U.S. Cl. CPC H01L 21/2236; H01L 21/2256

(57) ABSTRACT

Disclosed is a method of performing doping by implanting a dopant to a processing target substrate. First, in an oxide film forming step, an oxide film is formed on the processing target substrate prior to performing a doping treatment. In addition, after the oxide film is formed on the processing target substrate, a plasma doping treatment is performed from a top of the oxide film after the oxide film forming step.

### CROSS-REFERENCE TO RELATED APPLICATIONS

This application is based on and claims priority from Japanese Patent Application No. 2014-262813, filed on Dec. 25, 2014, with the Japan Patent Office, the disclosure of which is incorporated herein in its entirety by reference.

### TECHNICAL FIELD

Exemplary embodiments disclosed herein relate to a doping method and a semiconductor element manufacturing method.

### BACKGROUND

Semiconductor elements such as, for example, a Large Scale Integrated circuit (LSI) and a Metal Oxide Semiconductor (MOS) transistor, are manufactured by performing processings such as, for example, doping, etching, Chemical Vapor Deposition (CVD), and sputtering, on a semiconductor substrate (wafer) as a substrate to be processed (hereinafter, referred to as a “processing target substrate”).

Here, doping methods include ion doping that is performed using an ion implanting apparatus, and a plasma doping method that implants radicals or ions of a dopant to a surface of an object to be processed (hereinafter, referred to as a “processing target object”) by directly using plasma. In addition, with respect to a Fin Field Effect Transistor (FinFET) having a three-dimensional structure, as a method of implanting a dopant impurity uniformly regardless of an irregularity area of the three-dimensional structure (conformal doping) has recently been requested very strongly, a plurality of doping methods using plasma have been tried and reported.

For example, a doping method using a doping treatment apparatus (plasma doping) includes a technique that performs doping on an entire three-dimensional structure by mainly generating ionic plasma and then scattering the generated ionic plasma.

In addition, as a recent attempt, a method of conformally implanting a dopant to a side wall of a FinFET using a method called Ion Assisted Deposition and Doping (IADD) has been introduced as a method of uniformly implanting a dopant to a side wall of a FinFET. The IADD refers to a method of additionally irradiating ions obliquely in relation to a deposited arsenic (As) film.

Here, the present disclosure has been made from a background that, in the case where doping is performed on the doping target object having a three-dimensional structure such as, for example, a FinFET type semiconductor element, what is requested is a high coating performance of making a doping depth or a dopant concentration from a surface of each location of a doping target object uniform, i.e., a high conformality (uniformity) in doping at the respective locations of the doping target object. See, for example, Hirokazu Ueda, Peter L. G. Ventzek, Masahiro Oka, Masahiro Horigome, Yuuki Kobayashi, Yasuhiro Sugimoto, Toshihisa Nozawa, and Satoru Kawakami, “Conformal doping of topographic silicon structures using a radial line slot antenna plasma source”, Journal of Applied Physics 115, 214904 (2014).

### SUMMARY

A doping method and a semiconductor element manufacturing method according to an aspect of an exemplary embodiment include: an oxide film forming step of forming an oxide film on a processing target substrate prior to performing a doping treatment; and a doping treatment step of performing a plasma doping treatment from a top of the oxide film after the oxide film forming step.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flowchart illustrating schematic steps of a doping method according to a first exemplary embodiment.

FIG. 2 is a schematic perspective view illustrating a portion of a FinFET type semiconductor element manufactured by a doping method according to a second exemplary embodiment.

FIG. 3 is a schematic sectional view illustrating a main portion of a doping apparatus according to the second exemplary embodiment.

FIG. 4 is a view illustrating a doping amount for a FinFET type semiconductor element in the case where a plasma doping treatment is performed.

FIG. 5 is a view illustrating an aspect ratio of a FinFET in a FinFET type semiconductor element, and a relative concentration ratio of implanted dopant.

FIGS. 6A to 6C are views for describing a dopant transmission state in a top wall of a fin of a semiconductor element in a case where the plasma doping treatment was performed from the top side of a radical oxide film.

FIGS. 7A to 7C are views for describing a dopant transmission state in side walls of a fin of a semiconductor element in the case where the plasma doping treatment was performed from the top side of the radical oxide film.

FIG. 8 is a flowchart illustrating schematic steps of a doping method according to the second exemplary embodiment.

FIGS. 9A to 9C are views for describing a relationship between an ion glancing angle and a doping depth in a doping treatment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the conventional technology, there is a problem in that doping cannot be conformally performed on a doping target object having a three-dimensional structure such as, for example, a FinFET type semiconductor element.

For example, in the ion doping of the conventional IADD, since an ion irradiation amount for a location hidden as the three-dimensional structure of the FinFET type semiconductor element serves as a three-dimensional barrier becomes smaller than that on the top wall of a fin, completely conformal (uniform) doping is impossible. Referring to a more detailed example, in the case where doping is performed using ion beams, the ion beans are irradiated at an angle of 45 degrees in relation to a substrate surface of the FinFET type semiconductor element for the purpose of doping all of the top walls, side walls, and bottom walls of the fins of the FinFET type semiconductor element. Thereafter, ion beams are irradiated at an angle of 135 degrees, in other words, at an angle of 45 degrees from the opposite side. As a result, in the case where the fins have a somewhat high height, irradiated ions do not reach a region in a side wall that is close to a bottom wall in the height direction of a fin, and the bottom wall.

In addition, in the conventional IADD, a method to overcome the fault of the ion doping described above has been reported in which an As-containing thin film, which is deposited at a low temperature using plasma, is formed in advance on the surface of fins, and then an ion component is irradiated by applying a bias electric field to knock As atoms into Si (fin bodies). However, the purpose of performing conformal doping on all of the top walls and side walls of the fin bodies has not been completely achieved.

In addition, in the technique of performing doping on an entire three-dimensional structure by scattering the generated ionic plasma, a plasma doping method has appeared in which a dopant (ions) generated by plasma is randomly irradiated, as ion species, to a surface of a three-dimensional structure by an ion drawing mechanism which is an extension plate. However, all the test data shown by this method did not show that conformal doping can be performed such that the dopant concentration is uniform over all of the top walls and side walls of fin bodies even though the test data suggested that the thickness of an amorphous layer (a disorder layer of Si crystals containing the dopant) formed on the surface of the three-dimensional structure is conformal.

In other words, in the doping method using the above-mentioned doping treatment apparatus, only the layer thickness of a pre-amorphous layer generated as a result of doping is uniform, but the dopant concentration and doping depth do not become conformal merely by the doping treatment. In addition, for example, in the above-mentioned conventional technique, in a FinFET type semiconductor element having a three-dimensional structure, the implanted dopant concentration and doping depth at a position of a top wall (top), the implanted dopant concentration and doping depth at a position of a side wall (side), and the implanted dopant concentration and doping depth at a position of a bottom wall (bottom) are not uniform and the doping is not conformally performed.

On the contrary, the inventors of the present disclosure have found that conformality may be achieved by performing an annealing treatment just after the doping. However, a method of achieving conformality has not yet been established until now in the case where the annealing treatment cannot be performed just after the doping. For example, in the case where a mask made of, for example, a resist, which lacks heat resistance exists on an element after doping, or in the case where a contamination element may be diffused from a residual film generated due to the doping when a heat treatment is performed just after the doping, conformality cannot be achieved by the annealing treatment.

The present disclosure has been made in consideration of the forgoing problems, and an object of the present disclosure is to provide a doping method and semiconductor element manufacturing method that are capable of realizing conformal doing even if it is impossible to perform a heat treatment on a processing target substrate just after doping.

A doping method and a semiconductor element manufacturing method according to an aspect of an exemplary embodiment include: an oxide film forming step of forming an oxide film on the processing target substrate prior to performing a doping treatment; and a doping treatment step of performing a plasma doping treatment from a top of the oxide film after the oxide film forming step.

In addition, the doping method and the semiconductor element manufacturing method according to an exemplary embodiment may further include a removing step of removing the oxide film after the doping treatment step.

In addition, in the doping method and the semiconductor element manufacturing method according to an exemplary embodiment, the oxide film may be formed in a film thickness of 1 nm to 3 nm in the oxide film forming step.

In addition, in the doping method and the semiconductor element manufacturing method according to an exemplary embodiment, arsenic may be used as the dopant in the doping treatment step.

According to one aspect of the exemplary embodiments conformal doping may be realized even if a heat treatment of a processing target substrate cannot be performed just after doping.

### First Exemplary Embodiment

In the first exemplary embodiment, a film is formed on a processing target substrate prior to performing a doping treatment on the processing target substrate, and the doping treatment is performed from the upper side of the formed film. Here, the film is formed of a dopant permeable material in a thickness that allows the transmission of the dopant therethrough. In addition, the film may be a film that is removable through, for example, cleaning after doping without being influenced by the dopant implanted by the doping. More specifically, an oxygen-containing film corresponds to such a film.

When a doping treatment is performed after such a film is formed on a processing target substrate, the amount of the dopant that is transmitted to the processing target substrate under the film is controlled due to the existence of the film, and the amount of the dopant that is transmitted to the processing target substrate may be uniformized in respective areas regardless of irregularities of the processing target substrate.

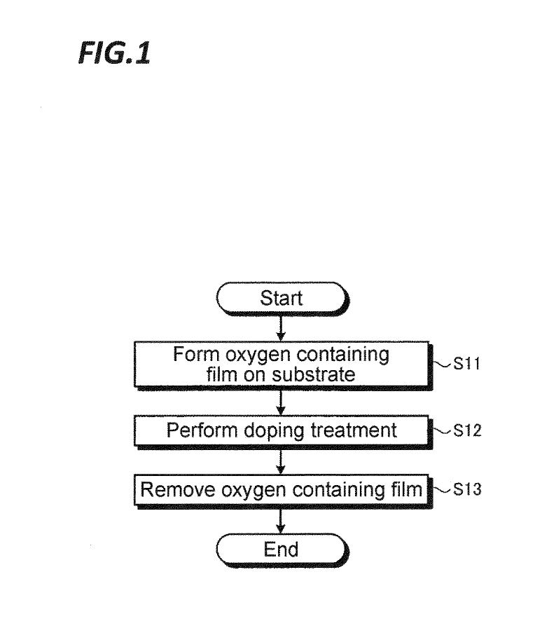

FIG. 1 is a flowchart illustrating schematic processes of a doping method according to a first exemplary embodiment. As illustrated in FIG. 1, in the doping method according to the first exemplary embodiment, first, an oxygen-containing film is formed on a processing target substrate (step S11). Next, a dopant is implanted into the processing target substrate from the upper side of the formed film to execute a doping treatment (step S12). When the doping treatment is completed, the oxygen-containing film formed on the processing target substrate is removed (step S13). By this, the doping method according to the first exemplary embodiment is terminated. A semiconductor element may be manufactured by realizing conformal doping using such a doping method.

(Effect of First Exemplary Embodiment)

According to the doping method and the semiconductor element manufacturing method according to the first exemplary embodiment, conformal doping may be realized even in a case where it is impossible to perform a heat treatment of the processing target substrate just after the doping since the conformal doping is achieved at the time of completing the doping treatment. For example, even in a case where a mask of a resist, which lacks a heat resistant property, exists on a doped element, desired conformality may be achieved. In addition, even in a case where there is concern that a contamination element may be diffused from a residual film produced by the doping when a heat treatment is performed just after the doping, the conformality may be realized without such trouble.

In addition, according to the doping method of the first exemplary embodiment, since the amount of dopant entering the processing target substrate under the film is controlled by the film on the processing target substrate, conformal doping may be achieved. In particular, since the transmission amount of dopant can be controlled by the film, the dopant can be distributed over respective portions, of which the ion implantation angles are different from each other, regardless the shape of the processing target substrate.

### Second Exemplary Embodiment

Next, descriptions will be made on an example in which conformal doping is achieved by performing plasma doping after an oxide film is formed on a FinFET type semiconductor element, as a second exemplary embodiment. First, descriptions will be made on an example of a FinFET type semiconductor element and a doping apparatus for performing the plasma doping.

(Example of FinFET Type Semiconductor Element)

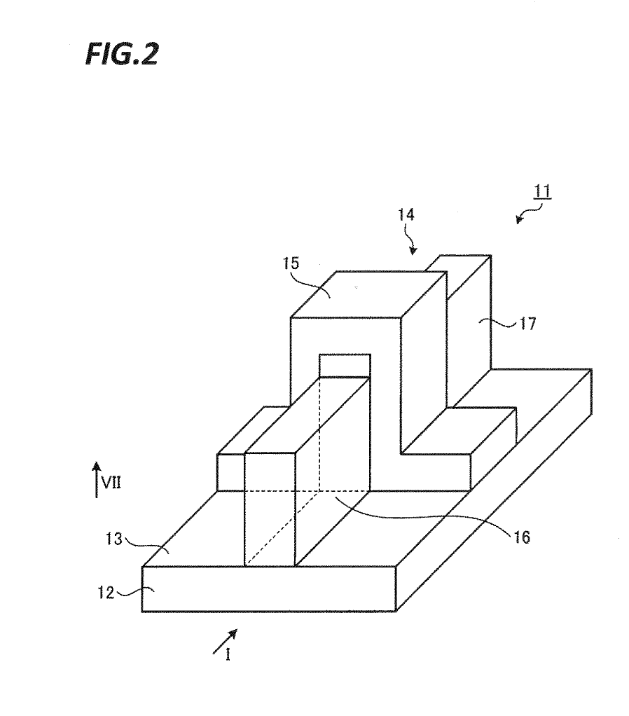

FIG. 2 is a schematic perspective view illustrating a portion of a FinFET type semiconductor element which is a semiconductor element manufactured by a doping method and a doping apparatus according to the exemplary embodiment. Referring to FIG. 2, a FinFET type semiconductor element 11 manufactured by a doping method and a doping apparatus according to one exemplary embodiment of the present disclosure includes a fin 14 that protrudes in a large elongation upwardly from a main surface 13 of a silicone substrate 12. The extension direction of the fin 14 is a direction indicated by arrow I in FIG. 2. The portion of the fin 14 has a substantially rectangular shape when viewed in the direction of arrow I which is the lateral direction of the FinFET type semiconductor element 11. A gate 15 extending in a direction orthogonal to the extension direction of the fin is formed to cover a portion of the fin 14. In the fin 14, a source 16 is formed at the front side of the formed gate 15, and a drain 17 is formed at the depth side. With respect to the shape of the fin 14, that is, the surface of the protrusion protruding upward from the main surface 13 of the silicon substrate 12, doping is performed by plasma generated using microwaves.

In addition, although not illustrated in FIG. 2, depending on the manufacturing process of the semiconductor element, a photoresist layer may be formed in a step prior to performing the doping. The photoresist layer is formed on lateral sides of the fin 14, for example, portions positioned at the left and right sides on the paper of FIG. 2 to be spaced apart from each other. The photoresist layer is formed to extend in the same direction as the fin 14 and protrudes in a large elongation upwardly from the main surface 13 of the silicon 12.

(Example of Doping Apparatus According to Second Exemplary Embodiment)

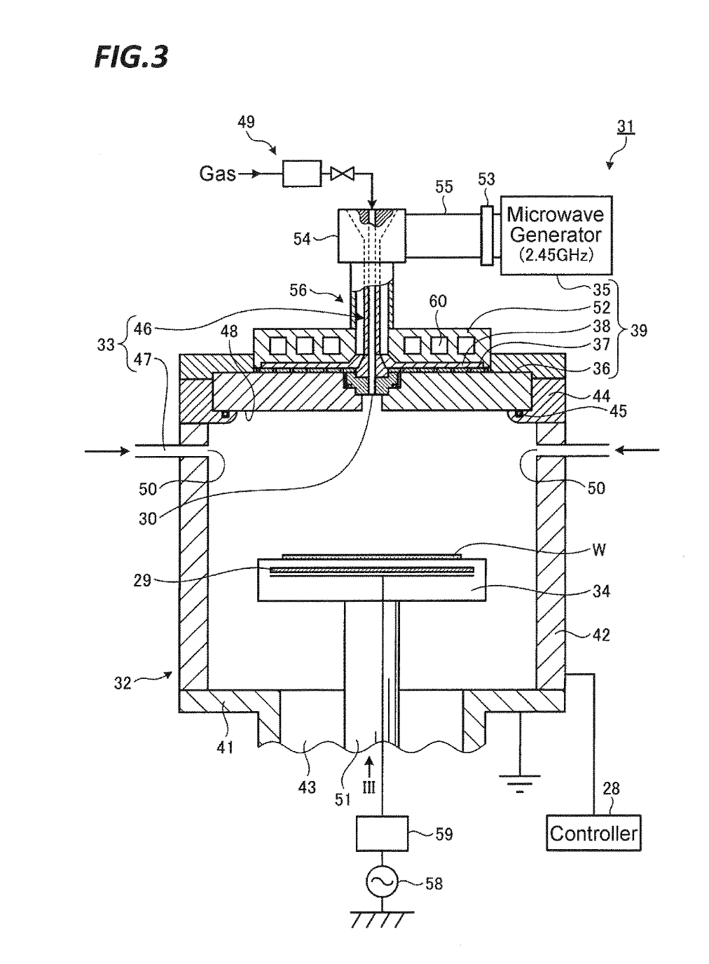

FIG. 3 is a schematic sectional view illustrating a main portion of a doping apparatus according to the second exemplary embodiment. In addition, in FIG. 3, hatching is omitted for some components for easy understanding. In addition, in the present exemplary embodiment, the up-and-down direction on the paper of FIG. 3 is referred to as the up-and-down direction of the doping apparatus.

Referring to FIG. 3, the doping apparatus 31 includes: a processing container 32 within which doping is performed on a processing target substrate W; a gas supply section 33 that supplies a plasma excitation gas or a doping gas to the inside of the processing container 32; a disc-shaped holding table 34 that holds the processing target substrate W thereon; a plasma generation mechanism 39 that generates plasm within the processing container 32 using microwaves; a pressure adjustment mechanism that adjusts the pressure within the processing container 32; a bias power supply mechanism that supplies an AC (alternating current) bias power to the holding table 34; and a controller 28 that controls operations of the entire doping apparatus 31. The controller 28 controls various parameters of the entire doping apparatus 31, for example, the gas flow rate in the gas supply section 33, the pressure within the processing container 32, and the bias power supplied to the holding table 34.

The processing container 32 includes a bottom portion 41 positioned below the holding table 34, and a side wall extending upwardly from the outer periphery of the bottom portion 41. The side wall 42 has a substantially cylindrical shape. In the bottom portion 41 of the processing container 32, an exhaust port 43 is provided through a portion of the bottom portion 41 to exhaust the gas. The top side of the processing container 32 is opened, and the processing container 32 is configured to be sealed by a cover unit 44 placed on the top side of the processing container 32, a dielectric window 36 to be described later, and an O-ring 45 as a seal member interposed between the dielectric window 36 and the cover unit 44.

The gas supply section 33 includes a first gas supply section 46 that injects a gas toward the center of the processing target substrate W, and a second gas supply section 47 that injects a gas from the outside of the processing target substrate W. A gas supply hole 30 that supplies in the first gas supply section 46 is provided at the center in the diametric direction of the dielectric window 36 and at a position retreated to the inner side of the dielectric window 36 from the bottom surface 48 of the dielectric window 36 which becomes an opposite surface to the holding table 34. The first gas supply section 46 supplies an inert gas for plasma excitation or a doping gas while adjusting, for example, a flow rate, by a gas supply system 49 connected to the gas supply section 46. The second gas supply section 47 is formed by providing a plurality of gas supply holes 50 that supply the inert gas for plasma excitation or the doping gas to the inside of the processing container 32 in a portion of the upper side of the side wall 42. The plurality gas supply holes 50 are provided in the circumferential direction at regular intervals. The first gas supply section 46 and the second gas supply section 47 are supplied with the same kind of inert gas for plasma excitation or doping gas from the same gas supply sources. In addition, according to, for example, a request or control contents, separate gases may be supplied from the first gas supply section 46 and the second gas supply section 47, and, for example, the flow rate ratio of the separate gases may be adjusted.

In the holding table 34, a high frequency power supply 58 for radio frequency (RF) bias is electrically connected to an electrode within the holding table 34 through a matching unit 59. The high frequency power supply 58 is capable of outputting high frequency waves of, for example, 13.56 MHz, at a predetermined power (bias power). The matching unit 59 accommodates a matcher that matches an impedance of the high frequency power supply 58 side with a load side impedance mainly of the electrode, plasma, and the processing container 32, and a blocking condenser for self-bias generation is accommodated in the matcher. In addition, during the doping, the supply of the bias voltage to the holding table 34 properly varies as needed. The controller 28 controls the AC bias power supplied to the holding table 34, as a bias power supply mechanism.

The holding table 34 is capable of holding the processing target substrate W thereon by an electrostatic chuck (not illustrated). The holding table 34 is supported on an insulative cylindrical support 51 that extends vertically upward from the lower side of the bottom portion 41. The exhaust port 43 is provided through a portion of the bottom portion 41 of the processing container 32 along the outer circumference of the cylindrical support 51. An exhaust apparatus (not illustrated) is connected to the lower side of the annular exhaust port 43 through an exhaust pipe (not illustrated). The exhaust apparatus includes a vacuum pump such as, for example, a turbo molecular pump. By the exhaust apparatus, the inside of the processing container 32 may be decompressed to a predetermined pressure. The controller 28 adjusts the pressure within the processing container 32 by, for example, controlling the exhaust by the exhaust apparatus, as a pressure adjustment mechanism.

The plasma generation mechanism 39 includes a microwave generator 35 that is provided outside the processing container 32 to generate microwaves for plasma excitation. In addition, the plasma generation mechanism 39 includes a dielectric window 36 that is arranged at a position opposite to the holding table 34 and introduces the microwaves generated by the microwave generator 35 into the processing container 32. In addition, the plasma generation mechanism 39 includes a slot antenna plate 37, which is provided with a plurality of slots 40, is placed above the dielectric window 36, and radiates microwaves to the dielectric window 36. In addition, the plasma generation mechanism 39 includes a dielectric member 38 that is placed above the slot antenna plate 37 to propagate the microwaves introduced from a coaxial waveguide 56 to be described later in a diametric direction.

The microwave generator 35 with a matching element 53 is connected to the upper portion of the coaxial waveguide 56 that introduces microwaves through a mode converter 54 and a waveguide 55. For example, microwaves of a TE mode generated from the microwave generator 35 pass through the waveguide 55, and are converted into a TEM mode by the mode converter 54 and propagated from the coaxial waveguide 56. As the frequency of the microwaves generated in the microwave generator 35, for example, 2.45 GHz is selected.

The dielectric window 36 is formed of a dielectric material substantially in a disc-shape. As a specific material of the dielectric window 36, for example, quartz or aluminum may be exemplified.

The slot antenna 37 has a thin disc shape. Here, the slot antenna plate 37 may be a radial line slot antenna.

The microwaves generated by the microwave generator 35 are propagated through the coaxial waveguide 56. The microwaves are radiated to the dielectric window 36 from the plurality of slots 40 provided in the slot antenna plate 37 interposed in a region extending radially toward the diametrical outside between a cooling jacket 52 and the slot antenna plate 37. The cooling jacket 52 includes a circulation path 60 that circulates coolant therein to adjust the temperature of for example, the dielectric member 38. The microwaves, which have been transmitted through the dielectric window 36, generate an electric field just below the dielectric window 36, thereby generating plasma within the processing container 32.

As described above, the plasma generation mechanism includes the dielectric window 36 provided at a position where the dielectric window is exposed within the processing container 32 and is opposite to the holding table 34. Here, the shortest distance between the dielectric window 36 and the processing target substrate W held on the holding table 34 is set to be in a range of 5.5 cm to 15 cm.

In the case where microwaves are generated in the doping apparatus 31, a so-called plasma generation region, in which the electron temperature of plasma is relatively high, is formed just below the bottom surface 48 of the dielectric window 36, more specifically in the region positioned below about several centimeters from the bottom surface 48 of the dielectric window 36. In addition, in the region positioned vertically downward therefrom, a so-called plasma diffusion region is formed in which the plasma generated in the plasma generation region is diffused. The plasma diffusion region has a relatively low electron temperature in the plasma, and a plasma doping treatment, i.e., doping is performed in the plasma diffusion region. In addition, in the case where microwave plasma is generated in the doping apparatus 31, the electron density of plasma gets relatively higher. As such, so-called plasma damage is not imparted to the processing target substrate W at the time of doping, and due to the high electron density of plasma, efficient doping, more specifically, for example, reduction of a length of doping time, can be achieved.

Here, in inductive coupling plasma of a general plasma source (e.g., ICP), the generated amount of high energy ions is very largely increased compared to radicals and low energy ion components in the plasma, Therefore, plasma irradiation damage to the processing target substrate is also increased. On the contrary, by using the microwave plasma, efficient generation of radicals and low energy ion components is enabled in a high pressure zone where the pressure advantageous for achieving conformal doping is 100 mTorr or higher. In addition, by using the microwave plasma, radicals (active species) are not affected by the plasma electric field. That is, since the plasma is electrically neutral, plasma irradiation damage to the processing target substrate may be overwhelmingly alleviated compared to ions.

(Distribution of Dopant Concentration in Top Wall and Side Wall of Three-Dimensional Device)

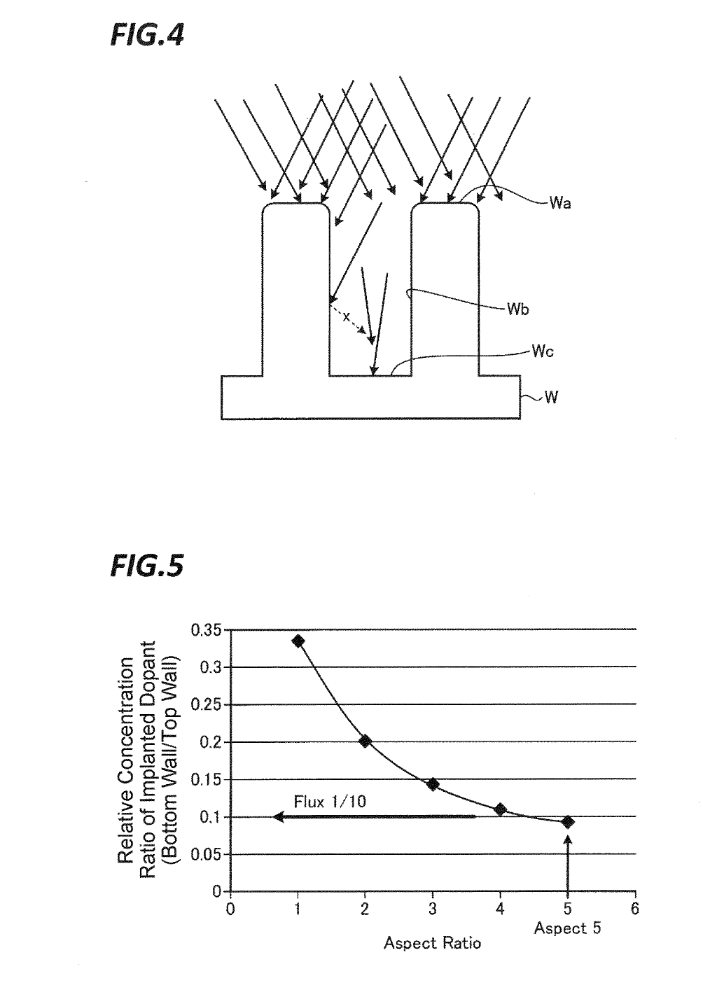

Next, as an example, descriptions will be made on a dopant concentration in a top wall and a side wall of a fin in the case where a FinFET type semiconductor element as illustrated in FIG. 2 is manufactured using a plasma doping treatment. FIG. 4 is a view illustrating a doping amount for a FinFET type semiconductor element in the case where a plasma doping treatment is performed. In the example illustrated in FIG. 4, the processing target substrate W is a FinFET type semiconductor element. Here, in the case where, for example, reflection is not considered, the components of radicals and low energy ion components reaching respective portions are different from each other due to the three-dimensional shape formed as a result of providing fins to the processing target substrate W. For example, the radicals and low energy ion components, which are generated by the radial slot antenna, implant a dopant to the top walls Wa of the FinFET in the processing target substrate W when they come in contact with the top walls Wa of the FinFET. Among the radicals and low energy ion components that have not come in contact with the top walls Wa of the FinFET, the radicals and low energy ion components, which come in contact with the side walls Wb of the FinFET, implant the dopant to the side walls Wb of the FinFET. Among the radicals and low energy ion components that have not come in contact with the top walls Wa of the FinFET nor with the side walls Wb of the FinFET, the radicals and low energy ion components that come in contact with the bottom walls Wc of the FinFET implant the dopant to the bottom walls Wc of the FinFET. In other words, since a three-dimensional barrier is generated by the FinFET, the probability to be in contact with the radicals and low energy ion components is reduced in the order of the top walls Wa, the side walls Wb, and the bottom walls Wc in the processing target substrate W, and the implanted dopant concentration is also correspondingly reduced.

FIG. 5 is a view illustrating an aspect ratio of a FinFET in a FinFET type semiconductor element, and a relative concentration ratio of implanted dopant. The example illustrated in FIG. 5 represents a case in which, for example, it was assumed that the implanted concentration of dopant does not include a sticking factor, which may be caused due to a sputtering phenomenon, and there is no redistribution of rebounding atoms, which may be caused when ions collides against a wall. Concerning the dopant concentration represented in FIG. 5, a case of implementing arsenic (As) to a silicon substrate is represented. As illustrated in FIG. 5, when the aspect ratio is set to “1,” i.e., the ratio between the length of a top wall and the length of a side wall is set to “1:1,” the dopant concentration implanted to a bottom wall becomes about “0.35” in the case where the dopant concentration implanted to the top wall is assumed as “1.” In addition, when the aspect ratio is set to “5,” that is, when the ratio between the length of the top wall and the length of the side wall is set to “1:5,” the dopant concentration implanted to the bottom wall becomes about “0.1” in the case where the dopant concentration implanted to the top wall is assumed as “1.” As described above, it can be seen that in the case where doping is performed on a FinFET type semiconductor element using the plasma doping treatment, it is difficult to perform conformal doping in the case where only the plasma doping treatment has been performed.

(Control of Dopant Concentration in Second Exemplary Embodiment)

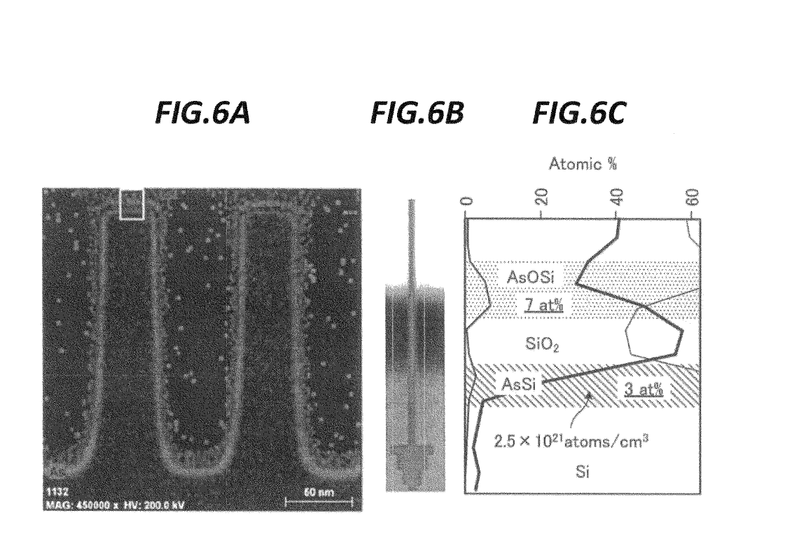

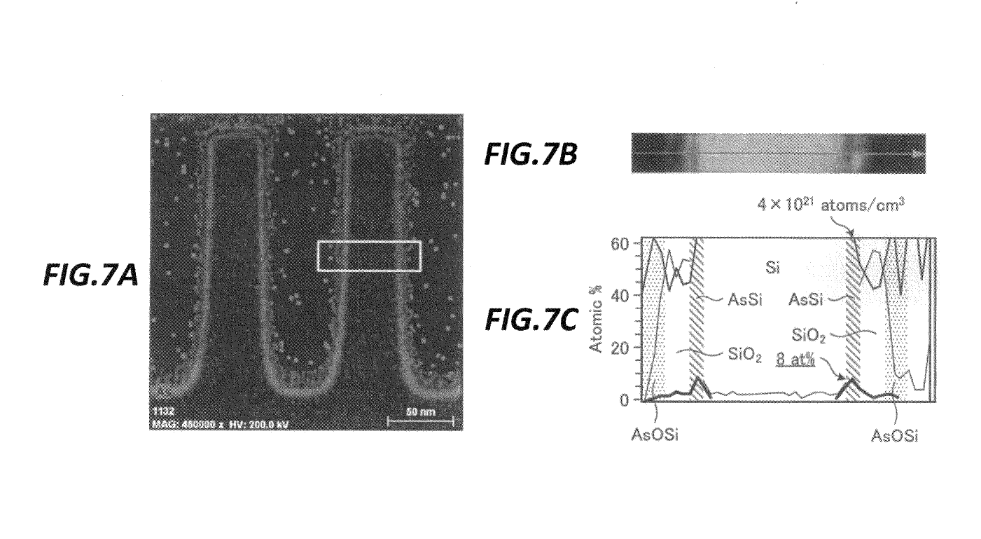

However, it has been found that when a plasma oxidation film is formed on a processing target substrate prior to performing the plasma doping treatment, and then the plasma doping treatment is performed, the plasma oxide film plays a role of controlling the transmission of the dopant so that a more uniform dopant concentration can be achieved in the top and side walls of the processing target substrate regardless of the shape of the processing target substrate. Next, descriptions will be made on a state of top and side walls of a processing target silicon substrate in the case where a plasm oxide film of about 2 nm to 3 nm was formed on the processing target silicon and a plasma doping treatment was performed using arsenic as a dopant with reference to FIGS. 6A to 6C and FIGS. 7A to 7C.

FIGS. 6A to 6C are views for describing a dopant transmission state in a top wall of a fin of a semiconductor element in the case where the plasma doping treatment was performed from the top side of a radical oxide film. FIGS. 7A to 7C are views for describing a dopant transmission state in a side wall of a fin of a semiconductor element in the case where the plasma doping treatment was performed from the top side of the radical oxide film.

In the examples illustrated in FIGS. 6A to 6C and FIGS. 7A to 7C, a fin of a semiconductor element was formed of silicon, and a silicon dioxide film (hereinafter, also referred to as an “oxide film” or a “radical oxide film”) having a film thickness of about 3 nm was formed on the silicon dioxide film by a radical oxidation treatment. In addition, a plasma doping treatment was performed from the top side of the oxide film using radial line slots. The width of the fin is about 50 nm. The measured arsenic concentrations indicated in FIGS. 6A to 6C and FIGS. 7A to 7C were obtained by performing arsenic mapping and by line-scanning a fin width of 50 nm using a Transmission Electron Microscope Energy Dispersive X-ray spectroscopy (TEM EDX).

In addition, in the examples of FIGS. 6A to 6C and FIGS. 7A to 7C, the plasma oxidation condition was adjusted by adjusting a plasm ON time such that the thickness of the oxide film becomes 3 nm. In addition, as the processing gases, argon (100%) of 1,000 sccm and O₂ of 100 sccm were used, and the pressure within the processing container was set to 100 mTorr. In addition, as the plasma doping condition, the microwave power was set to 5 kW and the pressure within the processing container was set to 230 mTorr. In addition, the gas flow rate of AsH₃ was set to 440 sccm, and the RF bias power was set to 150 W. In addition, the plasma doping time was set to 100 sec.

FIGS. 6A to 6C represent a dopant distribution in the top walls of the semiconductor element which was formed by forming an oxide film and performing doping under the conditions as described above. Among FIGS. 6A to 6C, FIGS. 6A and 6B are images obtained by the TEM EDX. In addition, FIG. 6C represents concentrations of respective materials in respective layers by bar graphs.

First, an analysis was performed for a portion enclosed by a white quadrangle in FIG. 6A using the TEM EDX. At this time, the distribution of the dopant (arsenic) at a location corresponding to the portion enclosed by the white quadrangle becomes as represented in FIG. 6C. That is, as represented in FIG. 6C, a layer containing AsOSi of 7 atomic % is formed on a radical oxide film (SiO₂) formed on the surface of the top wall. In addition, under the radical oxide film, a layer containing As of 3 atomic % is formed by the dopant implanted through the radical oxide film. That is, the dopant concentration in this portion is 2.5×10²¹ atoms/cm³. In addition, in FIG. 6C, the left polygonal line represents an arsenic (As) concentration, the central thick polygonal line represents an oxygen (O) concentration, and the right polygonal line represents a silicon (Si) concentration.

Next, descriptions will be made on a dopant distribution in the side walls of a fin with reference to FIGS. 7A to 7C. A dopant transmission state related to a portion indicated by a white quadrangle in FIG. 7A is represented in FIGS. 7B and 7C. As represented in FIG. 7C, an AsOSi film formed by doping exists on a silicon dioxide film (SiO₂) formed on the side walls of a fin. Meanwhile, a layer, in which the dopant transmitted through the silicon oxide film is distributed, exists (“AsSi” in FIG. 7C) under the silicon oxide film and has a dopant concentration of about 8 atomic %. The arsenic concentration of these portions (the portions indicated by lanes in FIG. 7C) is 4×10²¹ atoms/cm³. As can be seen from polygonal line graphs represented in FIG. 7C, the dopant concentration is high just below the oxide film. In addition, in FIG. 7C, the uppermost polygonal lines represent a silicon (Si) concentration, the middle polygonal lines represent an oxygen (O) concentration, and the lowermost polygonal lines represent an arsenic (As) concentration.

As can be seen from FIGS. 6A to 6C and FIGS. 7A to 7C, even if an oxide film is formed on the processing target substrate, the dopant can be transmitted through the oxide film when the film thickness of the oxide film is about 3 nm.

In addition, in the case where arsenic is injected as the dopant, the permissible concentration of arsenic to be implemented amorphous Si is constant as 5 E20 cm⁻³. Accordingly, the dopant may be implanted to the amorphous Si existing under the radical oxide film to the permissible limit. Accordingly, as the oxide film is formed, conformal doping may be achieved in a self-control manner using the low damage plasma doping characteristic of microwaves. Even in the examples illustrated in FIGS. 6A to 6C and FIGS. 7A to 7C, arsenic of a high concentration is detected in the interface between SiO₂ and Si. More specifically, arsenic of a concentration of 1 E21 cm⁻³ or higher is detected.

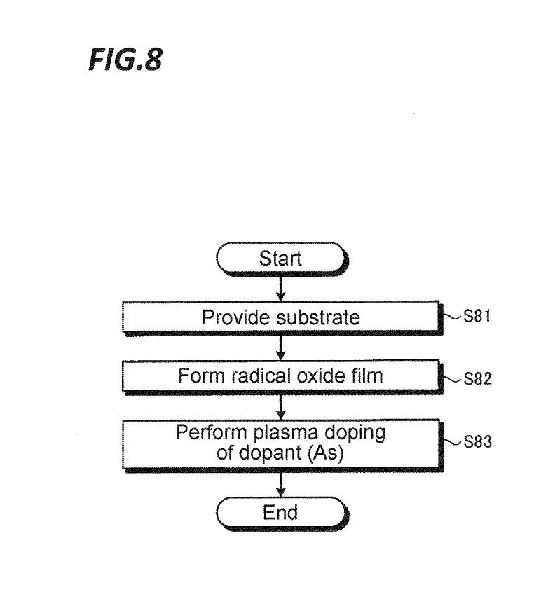

In a second exemplary embodiment, based on the foregoing knowledge, an oxide film is formed on a processing target substrate prior to performing a plasma doping treatment. FIG. 8 is a flowchart illustrating schematic steps of a doping method according to the second exemplary embodiment.

As illustrated in FIG. 8, first, a processing target substrate W is provided (step S81). In addition, a radical oxide film is formed on the processing target substrate W using, for example, a radical oxidation treatment (step S82). In addition, a plasma doping treatment is performed from the top side of the formed radical oxide film using arsenic as the dopant (step S83). By this, a uniform dopant concentration may be realized in respective portions of the processing target substrate W regardless of the shape of the processing target substrate W or an ion glancing angle, and conformal doping may be achieved.

In addition, in the second exemplary embodiment, the film thickness of the oxide film is set to be in a range of about 1 nm to 3 nm. When the film thickness of the oxide film is larger than 3 nm, it is evident in calculations that arsenic atoms activated by microwave plasma lack a vibrational energy sufficient to penetrate the oxide film in the side walls of the fin. Therefore, the upper limit of the film thickness is set to 3 nm.

In addition, it is also possible to increase the irradiation intensity of the activated arsenic ions in the plasma by intensively applying the RF bias power. In such a case, however, the irradiation intensity of the arsenic ions will be incident perpendicularly to the processing target substrate and conformal doping cannot be achieved. That is, when an electric field of 1 eV is applied by increasing the RF bias power, the doping depth is largely changed by the ion glancing angle. That is, the incident energy of ions in relation to the side walls becomes very small compared to the incident energy of ions in relation to the top wall in the perpendicular direction.

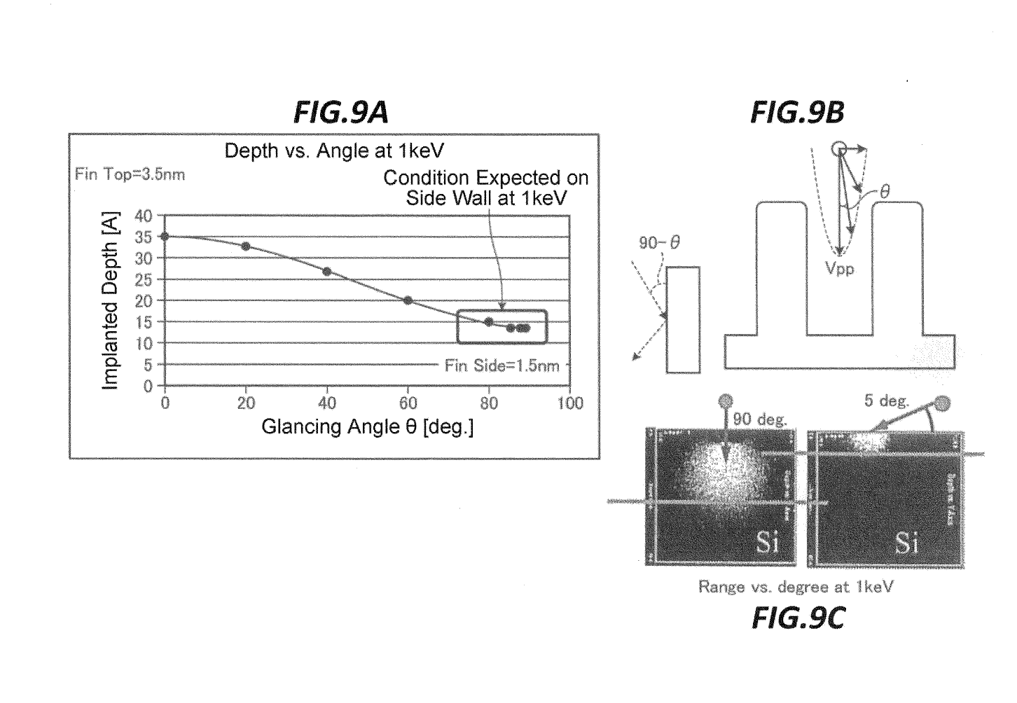

FIGS. 9A to 9C are views for describing a relationship between an ion glancing angle and a doping depth in a doping treatment. FIG. 9A is a graph representing a relationship between an ion glancing angle and a doping depth. As represented in FIG. 9A, in the case where the doping is performed while applying a bias power of 1 keV, the doping depth becomes gradually shallower as the ion glancing angle θ varies from 0 degrees to 90 degrees. For example, in the case where the ion glancing angle θ in relation to the top wall of the fin is set to zero (0) degrees, that is, in the case where the dopant is implanted perpendicularly to the surface of the top wall, the doping depth becomes about 3.5 nm. Whereas, in the case where the ion glancing angle θ in relation to the side wall of the fin is set to 80 degrees, thereby implanting the dopant from an oblique direction, the implantation depth of the dopant becomes about 1.5 nm. FIG. 9C represents more specifically the change of the doping depth following the change of the ion glancing angle. As represented in FIG. 9C, the doping depth is changed depending on the glancing angle, and conformal doping is not achieved merely by changing the irradiation intensity by adjusting the bias power.

As described above, the doping depth is largely changed depending on the ion glancing angle. Therefore, it is difficult to achieve a substantially uniform concentration in a desired depth merely by adjusting the RF bias power.

Whereas, in the second exemplary embodiment, as the oxide film is formed, the dopant concentration between the corresponding oxide film and the processing target substrate under the oxide film may be adjusted, and conformal doping may be achieved by realizing a uniform dopant concentration in respective portions regardless of for example, the shape of the processing target substrate.

(Effect of Second Exemplary Embodiment)

As described above, the doping method and semiconductor element manufacturing method according to the second exemplary embodiment include an oxide film forming step of forming an oxide film on a processing target substrate prior to performing a doping treatment, and a doping treatment step of performing a plasma doping treatment from the top of the oxide film after the oxide film forming step. In this way, the amount of the dopant transmitted through the corresponding oxide film may be controlled by forming the oxide film in advance on the processing target substrate. Therefore, according to the doping method and semiconductor element manufacturing method according to the second exemplary embodiment, conformal doping may be achieved by controlling the amount of the dopant using the oxide film, even if, for example, an annealing treatment cannot be performed after the doping treatment. For example, even if a mask of, for example, a resist, which lacks a heat resistance property, exists on a doped element, desired conformality may be achieved. In addition, even in the case where there is a concern that a contamination element may be diffused from a residual film produced by the doping when a heat treatment is performed just after the doping, conformal doping may be realized without such a trouble.

In addition, according to the doping method and the semiconductor element manufacturing method according to the second exemplary embodiment, since the amount of the dopant entering the processing target substrate below the oxide film is controlled by the oxide film on the substrate, conformal doping may be achieved regardless of the shape of the substrate. In particular, even in the case of a FinFET type semiconductor element or the like, the dopant may be diffused substantially uniformly in the side walls of fins as well as the top walls of the fins. In addition, while descriptions have been made, by way of an example, based on a FinFET type semiconductor element in the second exemplary embodiment, conformal doping may be realized by applying the second exemplary embodiment to even a semiconductor element having a different three-dimensional shape without being limited thereto.

In addition, according to the doping method and the semiconductor element manufacturing method according to the second exemplary embodiment, a uniform dopant concentration may be achieved in a desired depth in respective portions of a processing target substrate without relying on an ion glancing angle. Therefore, conformal doping may be easily achieved regardless of, for example, the shape of the semiconductor element.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of performing doping by implanting a dopant to a processing target substrate, the method comprising:
forming an oxide film on the processing target substrate prior to performing a doping treatment; and
performing a plasma doping treatment from a top side of the oxide film after the oxide film forming step.

2. The method of claim 1, further comprising:
removing the oxide film after the performing the plasma doping treatment.

3. The method of claim 1, wherein in the forming the oxide film, the oxide film is formed in a film thickness of 1 nm to 3 nm.

4. The method of claim 1, wherein in the performing the plasma doping treatment, arsenic is used as the dopant.

5. A method of manufacturing a semiconductor element, the method comprising:
forming an oxide film on a processing target substrate; and
performing a plasma doping treatment from a top side of the oxide film after the forming the oxide film.

6. The method of claim 5, further comprising:
removing the oxide film after the performing the plasma doping treatment.

7. The method of claim 5, wherein in the forming the oxide film, the oxide film is formed in a film thickness of 1 nm to 3 nm.

8. The method of claim 5, wherein in the performing the plasma doping treatment, arsenic is used as the dopant.
